(19) United States
(12) Patent Application Publication
(10) Pub. No.: US 2013/0098670 A1
(43) Pub. Date: Apr. 25, 2013

(54) WIRING SUBSTRATE AND MANUFACTURING METHOD OF THE SAME

(71) Applicant: NGK SPARK PLUG CO., LTD., Nagoya-shi (JP)

(72) Inventors: Masahiro INOUE, Kounan-shi (JP); Atsuhiko SUGIMOTO, Kagamigahara-shi (JP)

(73) Assignee: NGK SPARK PLUG CO., LTD., Nagoya-shi (JP)

(21) Appl. No.: 13/659,294

(22) Filed: Oct. 24, 2012

(30) Foreign Application Priority Data
Oct. 25, 2011 (JP) 2011-233721

(51) Int. Cl. H05K 1/11; H05K 3/10

(52) U.S. Cl. 174/264; 29/846

(57) ABSTRACT

Embodiments of the present invention provide a wiring substrate that includes a structure where a plurality of projection electrodes are arranged within an electrode formation region on a substrate main surface. At least one among the plurality of projection electrodes has a larger outer diameter than an outer diameter of a via conductor and is a variant projection electrode which has a roughened upper surface. Embodiments of the present invention also provide methods for manufacturing wiring substrates having one or more of said variant projection electrode.

### CROSS REFERENCE TO RELATED APPLICATION

The present application claims priority from Japanese patent application 2011-233721, which was filed on Oct. 25, 2011, the disclosure of which is herein incorporated by reference in its entirety.

### BACKGROUND OF THE INVENTION

1. Field of the Invention

The present invention relates to a wiring substrate where a plurality of projection electrodes are arranged within an electrode formation region on a substrate main surface, and to a manufacturing method for the same.

2. Description of Related Art

In the related art, a wiring substrate (i.e., semiconductor package) formed by installing a component such as an IC chip is well known. Here, as a structure for enabling electrical connection to the IC chip, it has been proposed that a solder bump be formed on a plurality of connecting terminals arranged at the bottom surface side of the IC chip or on a pad (i.e., C4 pad: Controlled Collapsed Chip Connection Pad) which is a plurality of projection electrodes arranged on a substrate main surface of the wiring substrate. For example, see JP-A-2010-34324, specifically FIG. 2 and the like, and JP-A-2009-246166, specifically FIG. 4 and the like.

### BRIEF SUMMARY OF THE INVENTION

However, there is concern about an IC chip sliding off a pad due to a slip (e.g., misalignment) during the IC chip installation since the pad projects from the main surface of a substrate. As a result, a connection failure (e.g., open failure, short-circuit failure and the like) may occur between the individual pad and the IC chip. Therefore, there is concern about degradation of the reliability of the wiring substrate since the manufactured wiring substrate becomes defective.

The present invention is made in the light of the above-described problem and a primary object is to provide a wiring substrate which enables reliability to be improved by preparing a projection electrode suitable for connection to a component. In addition, a secondary object is to provide a desirable manufacturing method for obtaining the above-described excellent wiring substrate.

As means (means 1) for solving the above-described problem, there is provided a wiring substrate which includes a multilayer portion which has a substrate main surface and a substrate reverse surface, the multilayer portion including interlayer insulation layers and a conductor layer that are layered. A plurality of projection electrodes are arranged within an electrode formation region on the substrate main surface, and via conductors, which electrically connect the plurality of projection electrodes and the conductor layer to each other, provided at a top layer, which is the interlayer insulation layer which forms the substrate main surface. At least one among the plurality of projection electrodes has a larger outer diameter than the outer diameter of the via conductor and is a variant projection electrode which has a roughened upper surface.

Therefore, according to the wiring substrate of the means 1, at least one among a plurality of the projection electrodes is formed as a variant projection electrode which has the roughened upper surface. Consequently, when placing a structure (for example, a connecting terminal arranged at the bottom surface side of a component or a solder bump formed on the connecting terminal) arranged at the bottom surface side of the component on the upper surface of the variant projection electrode, adhesive strength increases between the structure and the variant projection electrode. As a result, since misalignment of the structure is prevented by the structure coming into contact with the upper surface of the variant projection electrode, it is possible to prevent in advance the component from falling out of a plurality of the projection electrodes and to prevent a connection failure between the individual projection electrodes and the component. That is, it is possible to improve the reliability of the wiring substrate by providing the projection electrode suitable for being connected to the component.

The wiring substrate may be formed from any arbitrary material without being specifically limited, but for example, a resin substrate or the like is preferable. The preferable resin substrate includes a substrate formed from EP resin (epoxy resin), PI resin (polyimide resin), BT resin (bismaleimide-triazine resin), PPE resin (polyphenylene ether resin) or the like. In addition, a substrate formed from a composite material of the resin and glass fibers (glass woven fabric or glass non-woven fabric) may be used. As a specific example, there is a multilayer plate having high thermal resistance, such as a glass-BT composite substrate, a high Tg glass epoxy composite substrate (FR-4, FR-5 and the like) or the like. Furthermore, a substrate formed from composite material of the resin and organic fibers, such as polyamide fibers, may be used. Furthermore, a substrate formed from resin-resin composite material where thermosetting resin, such as epoxy resin impregnated in three-dimensional network-type fluorine-based resin base material such as continuous porous material PTFE, may be used. As another material, for example, it is possible to select various ceramics or the like. In addition, the structure of the relevant wiring substrate is not specifically limited, but it is possible to exemplify a build-up multilayer wiring substrate which has a build-up layer on one side or both sides of a core substrate, and a coreless wiring substrate which has no core substrate or the like.

The above-described wiring substrate includes the multilayer portion formed by layering the interlayer insulation layer and the conductor layer. The interlayer insulation layer can be arbitrarily selected in consideration of insulation properties, thermal resistance, humidity resistance and the like. As the preferable example of the material for forming the interlayer insulation layer, thermosetting resin, such as epoxy resin, phenol resin, urethane resin, silicon resin and polyimide resin or thermoplastic resin such as polycarbonate resin, acrylic resin, polyacetal resin and polypropylene resin, may be exemplified. In addition, a composite material of the resin and organic fibers such as glass fibers (glass woven fabric or glass non-woven fabric) or polyamide fibers, or a resin-resin composite material, where thermosetting resin such as epoxy resin is impregnated in three-dimensional network-type fluorine-based resin base material such as continuous porous material PTFE, may be used. Furthermore, a via hole may be formed at the interlayer insulation layer in advance in order to form the via conductor for interlayer connection.

The position and the number of the electrode formation regions on the substrate main surface are arbitrary without being specifically limited. However, for example, in a case of a so-called multi-cavity substrate, the electrode formation regions are present in numbers corresponding to the number of the cavities of the wiring substrate. The electrode formation region may be present only on the substrate main surface of the wiring substrate, but may be present at both the substrate main surface and the substrate reverse surface of the wiring substrate.

In addition, the projection electrode (including the variant projection electrode) can be formed from conductive metal material or the like. As the metal material configuring the projection electrode, for example, gold, silver, copper, iron, cobalt, nickel and the like are exemplified. In particular, it is preferable to form the projection electrode using copper which is highly conductive and which has low cost. In addition, it is good to form the projection electrode by plating. In such a case, the projection electrode can be uniformly formed with high accuracy. In contrast, if the projection electrode is formed using reflow of metallic paste, it is difficult to uniformly form the projection electrode with high accuracy. Accordingly, there is concern about variations occurring in the height of each projection electrode.

The variant projection electrode has a roughened upper surface. Furthermore, it is preferable for the variant projection electrode to have a roughened lateral surface in addition to the upper surface. In such a case, when heating and melting the solder bump placed on the upper surface of the variant projection electrode in a case of connecting the component to the variant projection electrode, the adhesive strength increases between the lateral surface of the variant projection electrode and the solder in addition to the adhesive strength between the upper surface of the variant projection electrode and the component. Therefore, the component can be more stably supported by the wiring substrate.

In addition, the surface roughness Ra of the variant projection electrode is arbitrary without being specifically limited, but for example, it is preferable to be 0.1 μm or more, more preferably from 0.1 μm to 0.6 μm. In contrast, if the surface roughness Ra of the variant projection electrode is less than 0.1 μm, even though the above-described structure is placed on the upper surface of the variant projection electrode, adhesive strength between the structure and the variant projection electrode does not become very high. Accordingly, it is difficult to prevent misalignment of the structure and thereby there is a possibility that the component cannot be prevented from falling out of a plurality of the projection electrodes. Herein, the “surface roughness Ra” indicated in the description is an arithmetic mean roughness Ra defined by JIS B0601. Furthermore, the method of measuring the surface roughness Ra is in accordance with JIS B 0651.

In addition, the plurality of projection electrodes can be arranged outside or within the electrode formation region, and it is preferable that all the projection electrodes which are present within the electrode formation region be variant projection electrodes. In such a case, since it is possible to prevent the misalignment of the above-described structure by the multiple variant projection electrodes, it is possible to more reliably prevent the component from falling out of a plurality of the projection electrodes. However, specifically in a case where a plurality of the projection electrodes are arrayed in vertical and horizontal rows along the surface direction of the substrate main surface in the electrode formation region, among a plurality of the projection electrodes, only the projection electrode positioned at the outer periphery of the electrode formation region may be the variant projection electrode.

In addition, the use of the variant projection electrode is not limited, but for example, the variant projection electrode may be the projection electrode which is in a flip chip interconnection with a connecting terminal arranged at a bottom surface side of a component via a solder bump placed on the upper surface of the variant projection electrode, which can be applied through heating and melting. That is, it is necessary that the projection electrode for the flip chip interconnection be formed to be small corresponding to miniaturizing of a so-called C4 pad. Accordingly, in a case where the projection electrode is in the flip chip interconnection, the characteristic problem of decreased reliability of the wiring substrate due to the failing of the component in the present invention easily occurs, and this is the reason why the significance of adopting the above-described means 1 increases.

Furthermore, the variant projection electrode may preferably have an equal outer diameter from an upper end to a lower end and may preferably be formed in the shape of a column as a whole. In this case, it is possible to relatively easily form the small variant projection electrode. Consequently, it is possible to further miniaturize the pitch between the projection electrodes.

The solder material for the solder bump is not specifically limited, but for example, tin-lead eutectic solder (Sn/37Pb: melting point 183° C.) is used. Sn/Pb based solder other than tin-lead eutectic solder, for example, solder having composition of Sn/36Pb/2Ag (melting point 190° C.) may be used. In addition to the solder containing lead as described above, lead-free solder such as Sn—Ag based solder, Sn—Ag—Cu based solder, Sn—Ag—Bi based solder, Sn—Ag—Bi—Cu based solder, Sn—Zn based solder and Sn—Zn—Bi based solder can be selected.

In addition, a preferable component for connection to the projection electrode can include, but is not limited to, a capacitor, a resistor, a semiconductor integrated circuit device (IC chip), or MEMS (Micro Electro Mechanical Systems) produced in the semiconductor manufacturing process. Furthermore, as the IC chip, it is possible to exemplify DRAM (Dynamic Random Access Memory), SRAM (Static Random Access Memory) and the like. Herein, the “semiconductor integrated circuit device” means a device mainly used as the microprocessor of a computer or the like.

As the other means (means 2) in order to solve the above-described problem, a method of manufacturing a wiring substrate includes preparing a multilayer portion which has a substrate main surface and a substrate reverse surface, the multilayer portion including interlayer insulation layers and a conductor layer that are layered; forming a via hole which penetrates a top layer, which is the interlayer insulation layer which forms the substrate main surface; a process of forming a resist on the top layer; forming an opening on the resist which has a larger inner diameter than that of the via hole; forming a via conductor at the via hole and a projection electrode at the opening by plating the inner side of the via hole and the opening; and forming a variant projection electrode by roughening an upper surface of the projection electrode.

Therefore, according to the method of manufacturing the wiring substrate of the means 2, the variant projection electrode which has the roughened upper surface is formed by performing the process of forming the variant projection electrode. Thus, if the structure (for example, the above-described connecting terminal, solder bump or the like) arranged at the bottom surface side of the component is placed on the upper surface of the variant projection electrode, the adhesive strength increases between the structure and the variant projection electrode. As a result, since the structure comes into contact with the upper surface of the variant projection electrode, misalignment of the structure is prevented. Therefore, it is possible to prevent in advance the component from falling out of a plurality of the projection electrodes and consequently it is possible to prevent connection failure between the individual projection electrodes and the component. That is, since it is possible to manufacture the wiring substrate which includes the projection electrode suitable for being connected to the component, reliability of the wiring substrate can be improved.

Hereinafter, the method of manufacturing the wiring substrate according to the means 2 will be described.

In the process of preparing the multilayer portion, the multilayer portion is prepared. In the subsequent process of forming the via hole, the via hole penetrating the top layer, which is the interlayer insulation layer forming the substrate main surface, is formed on the multilayer portion. In the subsequent process of forming the resist, the resist is formed on the top layer. In the subsequent process of forming the opening, the opening which is set to have a larger inner diameter than the inner diameter of the via hole is formed. As the method of forming the opening, a method of forming the opening by performing a drilling work to the resist, a method of forming the opening by performing a laser beam machining to the resist, a method of forming the opening by performing exposure and development, and a method of forming the opening on the resist by punching the resist using a punching die are exemplified.

In the subsequent process of forming the projection electrode, the via conductor is formed at the via hole by plating with the inner side of the via hole and the opening, and the projection electrode is formed at the opening. In the subsequent process of forming the variant projection electrode, the variant projection electrode is formed by roughening the upper surface of the projection electrode. Through the above processes, the wiring substrate is manufactured.

In the process of forming the variant projection electrode, as the method of roughening the upper surface of the projection electrode, it is possible to include a method of chemically roughening the upper surface of the projection electrode, a method of mechanically roughening the upper surface of the projection electrode and the like. In the process of forming the variant projection electrode, the method of chemically roughening the upper surface of the projection electrode includes a method of roughening the upper surface of the projection electrode by etching with respect to the projection electrode. In this case, fine roughening can be obtained.

On the other hand, in the process of forming the variant projection electrode, a method of mechanically roughening the upper surface of the projection electrode includes a method of roughening the upper surface by pressing the upper surface of the projection electrode using the pressing jig which has a rough pressing surface. In this case, since the upper surface of a plurality of the projection electrodes can be flattened in the process of forming the variant projection electrode, it is possible to reliably and easily obtain the wiring substrate which includes a group of the variant projection electrodes which are excellent in coplanarity and suitable for being connected to the component. In addition, even if the variant projection electrode is formed by metal plating (for example, such as gold plating) which is difficult to etch, it is possible to reliably roughen the upper surface by pressing the upper surface of the projection electrode using the pressing jig. Herein, the “coplanarity” indicates a uniformity of the bottom surface of a terminal defined in the “measuring method of dimensions in EIAJ ED-7304 BGA regulation, standards of Electronic Industries Association of Japan”.

Herein, the pressing jig is preferably configured of metal such as titanium or stainless steel, ceramics such as alumina, silicon nitride, silicon carbide or boron nitride, and glass. More specifically, the pressing jig is preferably configured using ceramics which enable high working accuracy and less deformation by heat. In addition, it is preferable that the rough pressing surface of the pressing jig is a flat plane. In this case, pressing power is equally applied to each projection electrode and thereby the upper surface of each projection electrode can be accurately roughened.

Furthermore, a surface plated layer which has a roughened surface corresponding to the shape of the upper surface of the variant projection electrode may be formed on the surface of the variant projection electrode by displacement plating after the process of forming the variant projection electrode. The displacement plating is not to form the plated layer so as to coat the surface of the variant projection electrode, but is to form the plated layer by replacing metal in the vicinity of the surface of the variant projection electrode. Accordingly, the displacement plating allows the roughened surface to have a desired surface roughness Ra since the uneven upper surface of the variant projection electrode is difficult to be filled in, even after plating.

### BRIEF DESCRIPTION OF THE DRAWINGS

FIG. 1 is a schematic cross-sectional view illustrating a configuration of a coreless wiring substrate according to an exemplary embodiment.

FIG. 2 is a schematic plan view illustrating the coreless wiring substrate.

FIG. 3 is a cross-sectional view of a coreless wiring substrate showing an enlarged view of a variant projection electrode.

FIG. 4 is an explanatory view illustrating a manufacturing method of a coreless wiring substrate.

FIG. 5 is an explanatory view illustrating a manufacturing method of a coreless wiring substrate.

FIG. 6 is an explanatory view illustrating a manufacturing method of a coreless wiring substrate.

FIG. 7 is an explanatory view illustrating a manufacturing method of a coreless wiring substrate.

FIG. 8 is an explanatory view illustrating a manufacturing method of a coreless wiring substrate.

FIG. 9 is an explanatory view illustrating a manufacturing method of a coreless wiring substrate.

FIG. 10 is an explanatory view illustrating a manufacturing method of a coreless wiring substrate.

FIG. 11 is an explanatory view illustrating a manufacturing method of a coreless wiring substrate.

FIG. 12 is an explanatory view illustrating a manufacturing method of a coreless wiring substrate.

FIG. 13 is an explanatory view illustrating a manufacturing method of a coreless wiring substrate.

FIG. 14 is a cross-sectional view of a coreless wiring substrate showing an enlarged view of a variant projection electrode according to another embodiment.

FIG. 15 is a cross-sectional view of a coreless wiring substrate showing an enlarged view of a variant projection electrode according to another embodiment.

FIG. 16 is a schematic cross-sectional view illustrating a configuration of a coreless wiring substrate according to another embodiment.

FIG. 17 is a schematic plan view illustrating a coreless wiring substrate according to another embodiment.

### DETAILED DESCRIPTION OF EXEMPLARY EMBODIMENTS OF THE INVENTION

Hereinafter, an exemplary embodiment of the present invention will be described in detail with reference to the drawings.

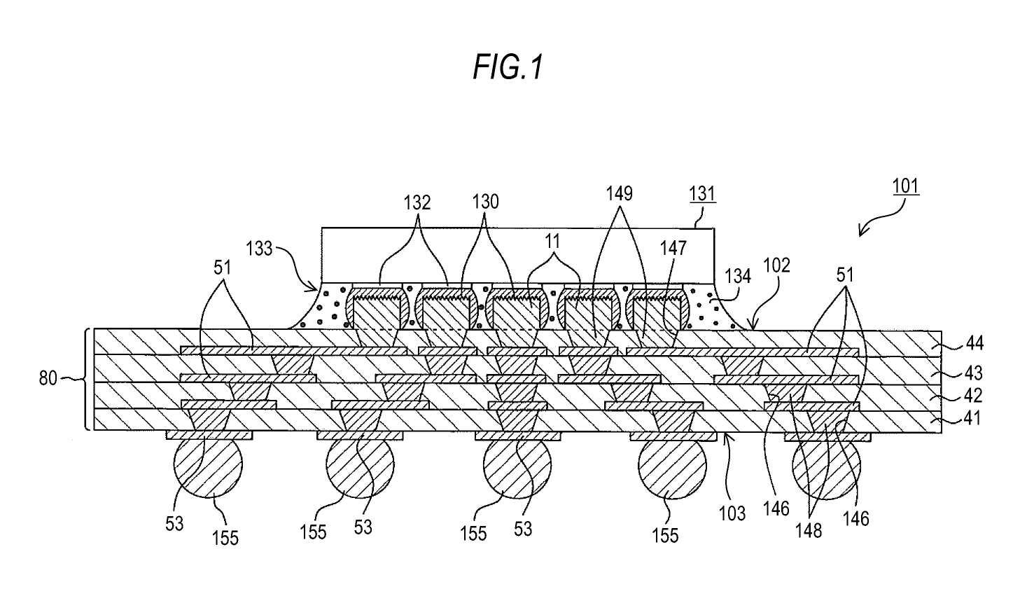

FIG. 1 is a schematic cross-sectional view illustrating a coreless wiring substrate 101 (wiring substrate) of the present embodiment. The coreless wiring substrate 101 does not have a core substrate and is a wiring substrate which has a structure where four layers of resin insulation layers 41, 42, 43 and 44 formed from an epoxy resin and conductor layers 51 formed from copper are alternately layered. The resin insulation layers 41 to 44 are interlayer insulation layers which have the same thickness and are formed from the same material.

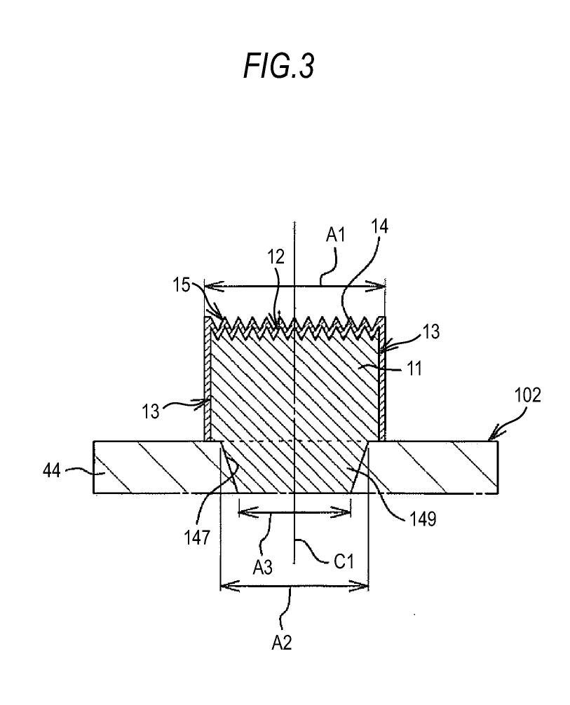

Furthermore, each of the resin insulation layers 41 to 44 respectively includes via holes 146 and 147, and via conductors 148 and 149. Each of the via holes 146 and 147 has a reverse truncated cone shape and is formed by drilling with respect to each of the resin insulation layers 41 to 44 using a YAG laser or a carbon dioxide laser. Each of the via conductors 148 is a conductor which has a diameter which expands in the same direction (upward in FIG. 1) and is mutually and electrically connected to each of the conductor layers 51. The outer diameter A2 (refer to FIG. 3) in the upper end of the respective via conductors 148 and 149 is set to be from 50 μm to 120 μm (100 μm in the present embodiment), and the outer diameter A3 (refer to FIG. 3) in the lower end of the respective via conductors 148 and 149 is set to be from 30 μm to 100 μm (60 μm in the present embodiment).

As illustrated in FIG. 1, BGA pads 53 are arrayed on a substrate reverse surface 103 (on the lower surface of the first layer, the resin insulation layer 41) of the coreless wiring substrate 101. A plurality of solder bumps 155 which have a height of approximately 400 μm to 600 μm is arranged on the surface of the respective BGA pads 53. Each of the solder bumps 155 is a so-called BGA bump which is used for electrically connecting to a terminal of a motherboard (not illustrated, mother substrate) side.

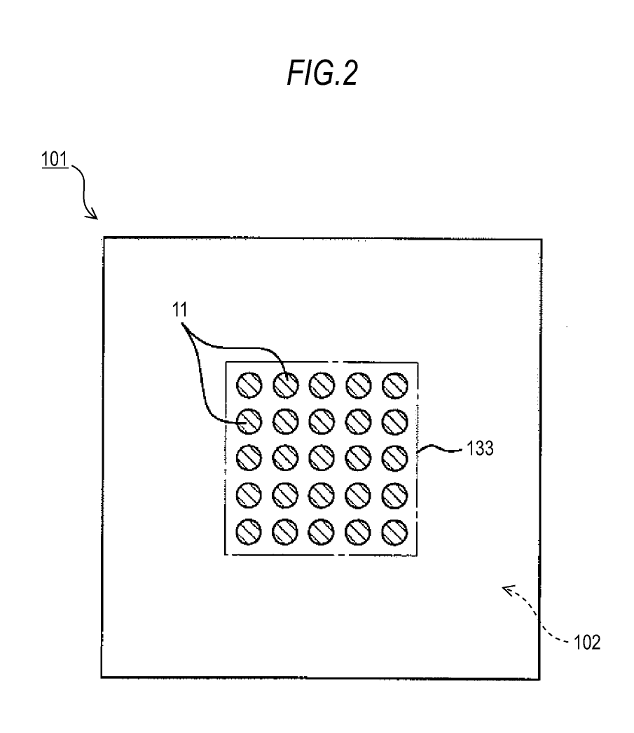

On the other hand, as illustrated in FIG. 2, an electrode formation region 133 which has a substantially rectangular shape in planar view is set to be formed on a substrate main surface 102 (on the surface of the top layer, the resin insulation layer 44) of the coreless wiring substrate 101. Then, a plurality of variant projection electrodes 11 is arranged vertically and horizontally along the surface direction of the substrate main surface 102 within the electrode formation region 133. In the present embodiment, all projection electrodes which are present within the electrode formation region 133 become variant projection electrodes 11.

As illustrated in FIG. 3, the variant projection electrodes 11 are set to have an equal outer diameter A1 from the upper end to the lower end and are formed in the shape of a column as a whole. Furthermore, the outer diameter A1 of the respective variant projection electrodes 11 is set to be from 50 μm to 140 μm (110 μm in the present embodiment). In addition, the respective variant projection electrodes 11 are integrally formed with the via conductors 149 provided at the top layer, the resin insulation layer 44, which has the substrate main surface 102, and are electrically connected to the conductor layers 51 via the via conductors 149. The outer diameter A1 of the variant projection electrodes 11 is set to be larger than the outer diameter A2 (100 μm) in the upper end of the via conductors 149 and the outer diameter A3 (60 μm) in the lower end of the via conductors 149. Furthermore, a center axis C1 of the variant projection electrodes 11 is consistent with the center axis of the via conductors 149. Then, the height of the variant projection electrodes 11 is set to be 60 μm.

As illustrated in FIG. 3, upper surfaces 12 of the respective variant projection electrodes 11 are roughened. A surface roughness Ra of the upper surfaces 12 is from 0.1 μm to 0.6 μm and is set to be 0.4 μm in the present embodiment. In addition, the respective variant projection electrodes 11 are configured by a copper layer (not illustrated), a nickel layer (not illustrated) and a gold layer 14. The copper layer is a plated layer which is integrally formed with the via conductors 149 by coating the inner surface of the via holes 147 and the substrate main surface 102 using electroless copper plating and copper electroplating. The nickel layer is the plated layer which is formed by coating the surface of the copper layer protruding from the substrate main surface 102 using electroless nickel plating. The gold layer 14 is the surface plated layer which is formed using electroless displacement gold plating with respect to the surface of the nickel layer.

In addition, as illustrated in FIG. 1, the respective variant projection electrodes 11 are designed to be connected to connecting terminals 132 arranged at the bottom surface of an IC chip 131 (component) which has a rectangular flat board shape, via solder bumps 130. That is, the solder bumps 130 are so-called C4 bumps which are used for flip chip interconnection with the connecting terminals 132 of the IC chip 131.

Then, an under filling 134 is filled in the clearance between the substrate main surface 102 and the IC chip 131. As a result, the coreless wiring substrate 101 and the IC chip 131 are mutually fixed to each other in a state where the clearance is sealed. In addition, the under filling 134 of the present embodiment is formed from an epoxy resin whose thermal expansion coefficient is approximately 20 to 60 ppm/° C. (specifically 34 ppm/° C.).

Next, a method of manufacturing the coreless wiring substrate 101 will be described.

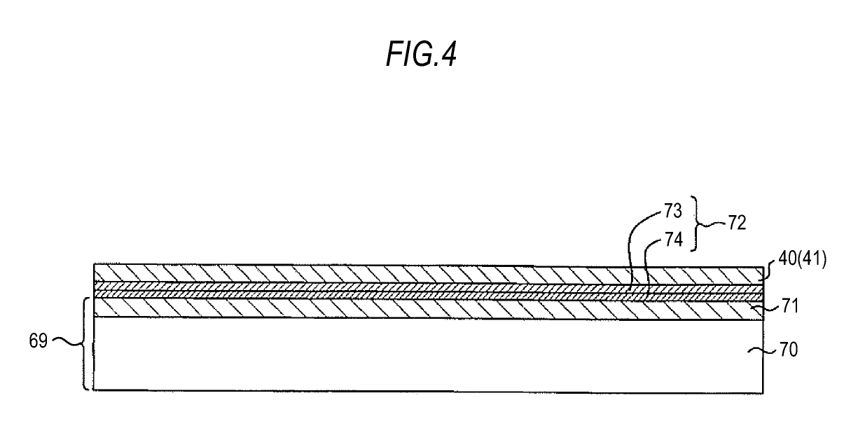

In a process of preparing a multilayer portion, a multilayer portion 80 which is to become an intermediate product of the coreless wiring substrate 101 is manufactured and prepared in advance. In addition, the intermediate product of the coreless wiring substrate 101 has a structure where product units which are to become the coreless wiring substrate 101 are plurally arranged along the plane direction. The intermediate product of the coreless wiring substrate 101 is manufactured in the following manner. First, a supporting substrate 70 having a sufficient strength, such as a glass epoxy substrate, is prepared (refer to FIG. 4). Next, a base member 69 formed from the supporting substrate 70 and a resin insulation base layer 71 is obtained in such a manner that a sheet-like insulation resin base member formed from an epoxy resin is attached in a half-hardening state and the resin insulation base layer 71 is formed on the supporting substrate 70 (refer to FIG. 4). Then, a layered metal sheet body 72 is arranged on one surface (specifically, the upper surface of the resin insulation base layer 71) of the base member 69 (refer to FIG. 4). Here, since the layered metal sheet body 72 is arranged on the resin insulation base layer 71 in the half-hardening state, the layered metal sheet body 72 comes to have secured adhesion to such an extent as not to be detached from the resin insulation base layer 71 during the next manufacturing processes. The layered metal sheet body 72 is made by adhering two sheets of copper foil 73 and 74 in a detachable state. More specifically, the layered metal sheet body 72 is formed by layering the respective copper foils 73 and 74 via metal plating (for example, chrome plating).

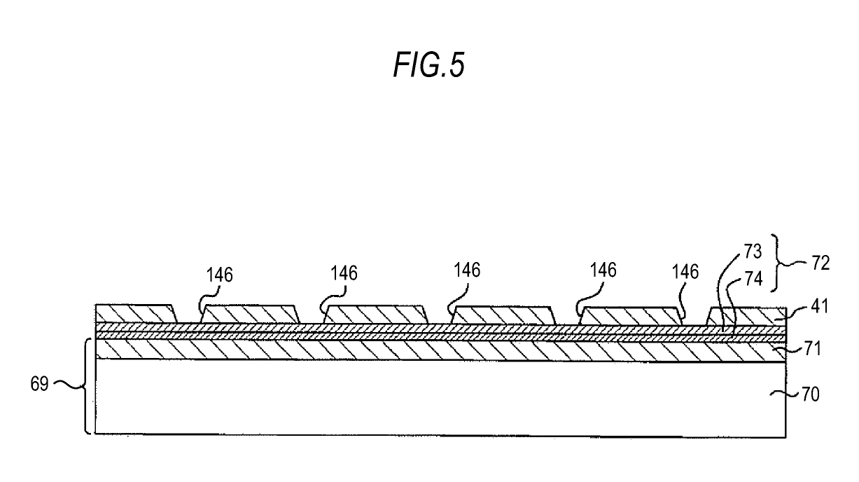

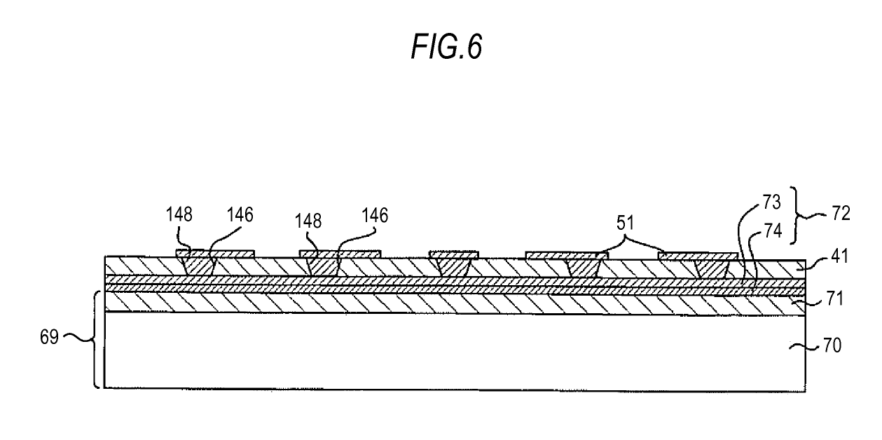

Then, a sheet-like insulation resin base member 40 is layered on the layered metal sheet body 72, and both are heated and pressurized in a vacuum state using a vacuum crimp thermal press machine (not illustrated). Thereby, the first layer, a resin insulation layer 41 is formed by hardening the insulation resin base member 40 (refer to FIG. 4). Then, as illustrated in FIG. 5, via holes 146 are formed at predetermined positions of the resin insulation layer 41 by laser beam machining and then desmear treatment is performed in order to remove smear inside the respective via holes 146. Thereafter, via conductors 148 are formed inside the respective via holes 146 using electroless copper plating and copper electroplating according to the well-known technique in the related art. In addition, the pattern of the conductor layers 51 (refer to FIG. 6) is formed on the resin insulation layer 41 by etching according to the well-known technology in the related art (for example, semi-additive process).

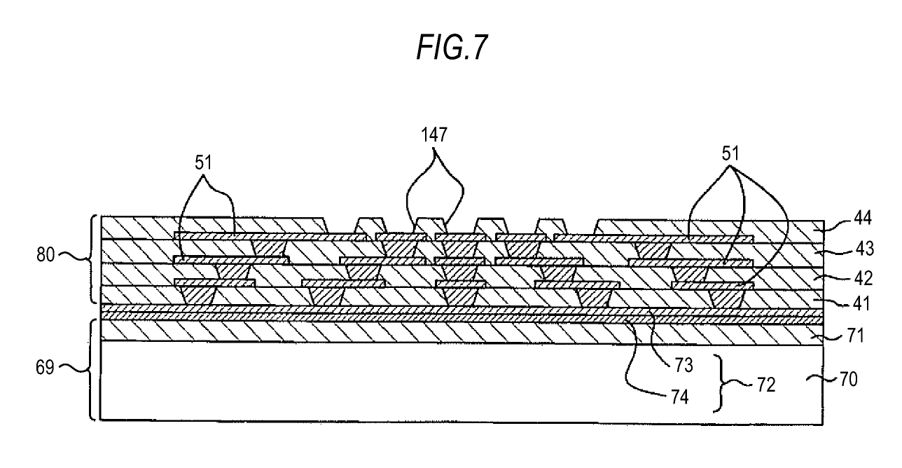

In addition, the second to the fourth layers, the resin insulation layers 42 to 44, and the conductor layer 51 are formed in the same manner as the above-described resin insulation layer 41 and the conductor layer 51 and are continuously layered on the resin insulation layer 41. According to the above manufacturing processes, a multilayer portion 80 formed by layering the layered metal sheet body 72, resin insulation layers 41 to 44 and the conductor layers 51 on the supporting substrate 70 is formed (refer to FIG. 7). Furthermore, as illustrated in FIG. 7, a region positioned on the layered metal sheet body 72 in the multilayer portion 80 becomes the multilayer portion 80 which is to become the intermediate product of the coreless wiring substrate 101. Then, a process of forming the via hole is performed and a via hole 147 penetrating the top layer, the resin insulation layer 44, is formed at the multilayer portion 80.

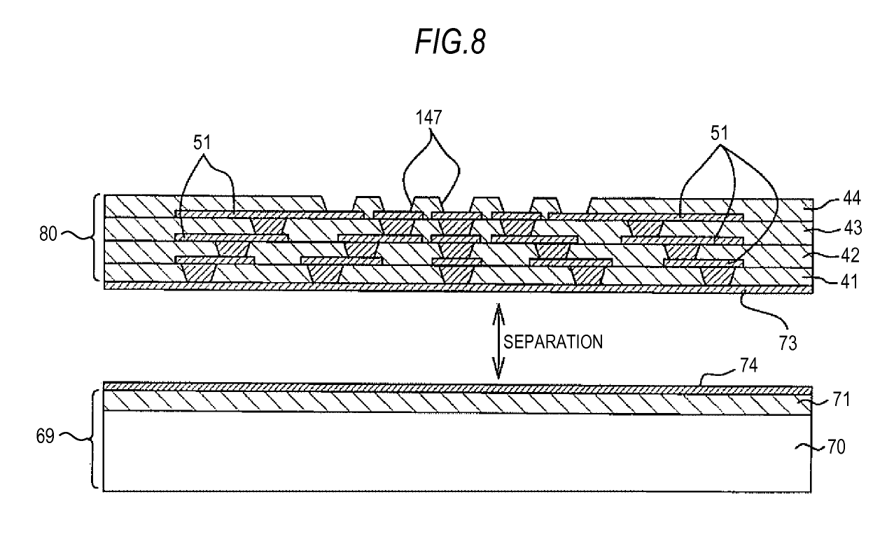

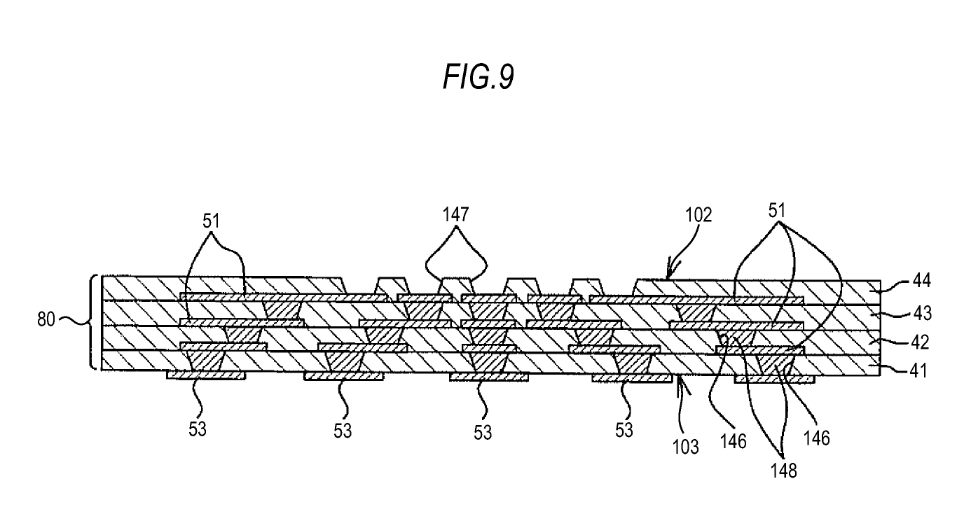

Next, the base member 69 is removed to expose a copper foil 73. More specifically, interfaces of two sheets of the copper foil 73 and 74 in the layered metal sheet body 72 are detached and the multilayer portion 80 is separated from the supporting substrate 70 (refer to FIG. 8). Then, patterning is performed by etching with respect to the copper foil 73 positioned on a substrate reverse surface 103 (lower surface) of the multilayer portion 80 (resin insulation layer 41). In this manner, BGA pads 53 are formed at the region on the substrate reverse surface 103 in the resin insulation layer 41 (refer to FIG. 9).

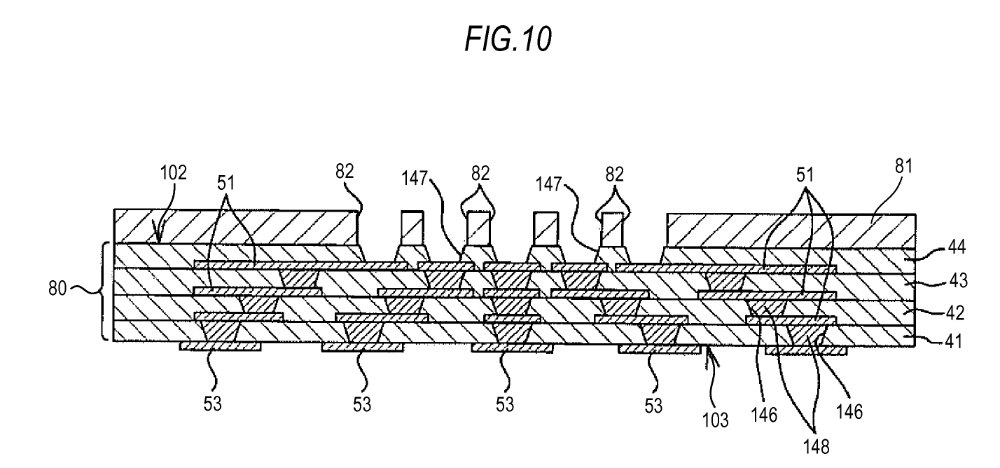

Next, a process of forming a resist is performed. Specifically, a dry film is laminated on the top layer, the resin insulation layer 44, and a plating resist 81 (refer to FIG. 10) is formed. In the subsequent process of forming an opening, laser beam machining is performed with respect to the plating resist 81 using a laser beam machine. As a result, openings 82 which are set to have a larger inner diameter than the inner diameter of via holes 147 are formed at the position which communicates with the via hole 147 of the resin insulation layer 44 (refer to FIG. 10).

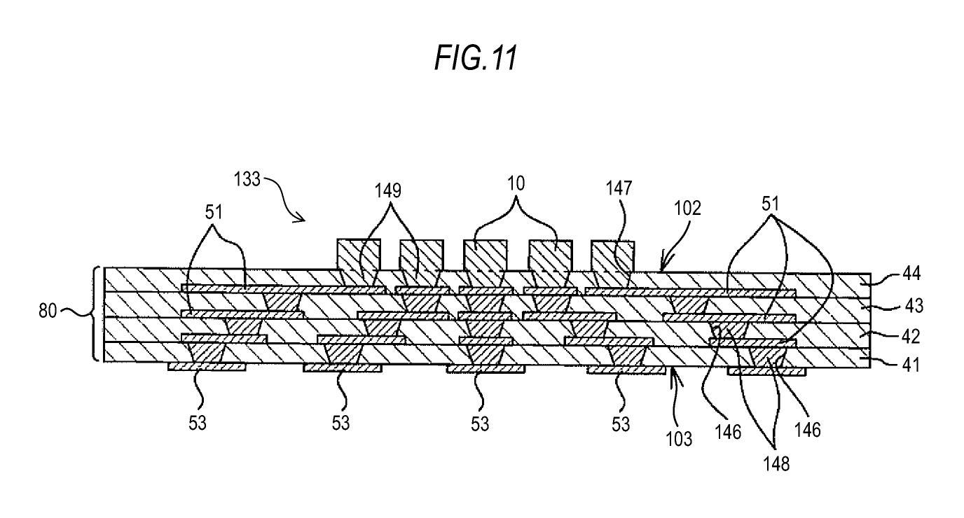

In the subsequent process of forming the projection electrode, plating is performed with respect to the inner side of the via holes 147 and the openings 82. Thereby, via conductors 149 (refer to FIG. 11) are formed at the via holes 147 and the projection electrodes 10 (refer to FIG. 11) are formed at the openings 82. More specifically, first, electroless copper plating and copper electroplating are performed and then a copper layer is formed with respect to the upper surface of the conductor layers 51 which are exposed to the inner surfaces of the via holes 147, the inner surfaces of the openings 82 and the bottom surfaces of the via holes 147. Next, electroless nickel plating is performed and thereby a nickel layer is formed on the surface of the copper layer which protrudes from the upper surface (substrate main surface 102) of the resin insulation layer 44. At this time, the projection electrodes 10 formed from the copper layer and the nickel layer are formed. Then, the plating resist 81 is detached (refer to FIG. 11). Here, the thickness of the copper layer is set to be approximately 50 μm and the thickness of the nickel layer is set to be from 0.01 μm to 15 μm. In addition, the copper layer and the nickel layer of the present embodiment are formed by plating, but can be formed using another method such as a sputtering method or CVD method. However, it is preferable to form the copper layer by plating in order to obtain a height (approximately 50 μm) required particularly for the copper layer.

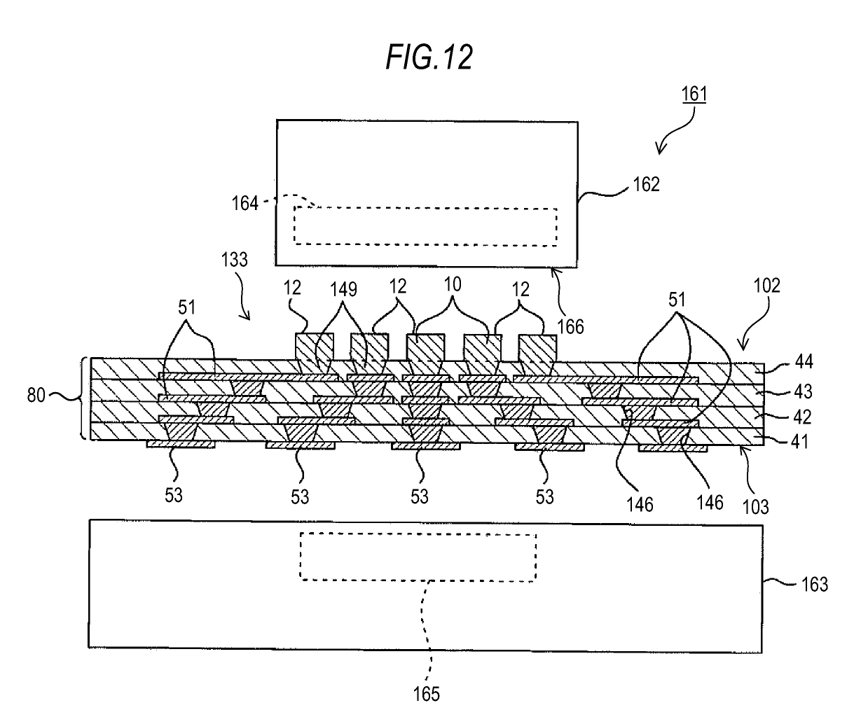

In the subsequent process of forming the variant projection electrode, the variant projection electrodes 11 are formed by roughening the upper surface 12 of the projection electrodes 10. More specifically, first, the multilayer portion 80 is set on an electrode roughening device 161 (refer to FIG. 12). In detail, the multilayer portion 80 is set on a moving jig (not illustrated) in a state where the substrate main surface 102 side faces upward. In addition, an upper jig 162 which is a pressing jig and a lower jig 163 which is a supporting jig are heated at 110° C. using electric heaters 164 and 165. Then, the coreless wiring substrate 101 is supported by the lower jig 163 through the transporting and lifting operation of the moving jig.

Next, the upper jig 162 is lowered and the upper surface 12 of each projection electrode 10 on the multilayer portion 80 is pressed using a rough pressing surface 166 of the upper jig 162. At this time, each upper surface 12 is pressed to have an aligned height. Then, an equal pressure is reliably applied to the upper surface 12 of each projection electrode 10 and the upper surface 12 is crushed. As a result, the projection electrode 10 is flattened and roughened. Thus, the variant projection electrode 11 is formed. In addition, the rough pressing surface 166 of the upper jig 162 is plane. In the present embodiment, the surface roughness Ra of the rough pressing surface 166 is set to be 0.4 μm. Then, the multilayer portion 80 which has finished the process of forming the variant projection electrode is transported to the outside of the device by the transporting and lifting operation of the moving jig.

After the process of forming the variant projection electrode, electroless displacement gold plating is performed and thereby the gold layer 14 (refer to FIG. 3) is formed with respect to the surface of the variant projection electrode 11 (nickel layer). At this time, the roughened surface 15 corresponding to the shape of the upper surface 12 of the variant projection electrode 11 is formed on the gold layer 14. In addition, the thickness of the gold layer 14 is set to be from 0.01 μm to 15 μm.

Next, solder bumps 155 are formed on a plurality of BGA pads 53 formed at the substrate reverse surface 103 side of the multilayer portion 80. More specifically, solder balls are arranged on the respective BGA pads 53 using a solder ball mounting device (not illustrated) and then the solder balls are heated for reflow soldering at a predetermined temperature. Thus, the solder bumps 155 are formed on the respective BGA pads 53. In addition, at this time, the intermediate product of the coreless wiring substrate 101 is completed.

In the subsequent separation process, the intermediate product of the coreless wiring substrate 101 is divided using the well-known cutting machine or the like. As a result, each product portion is divided and thereby the coreless wiring substrates 101 which are individual products can be plurally obtained at the same time (refer to FIG. 1).

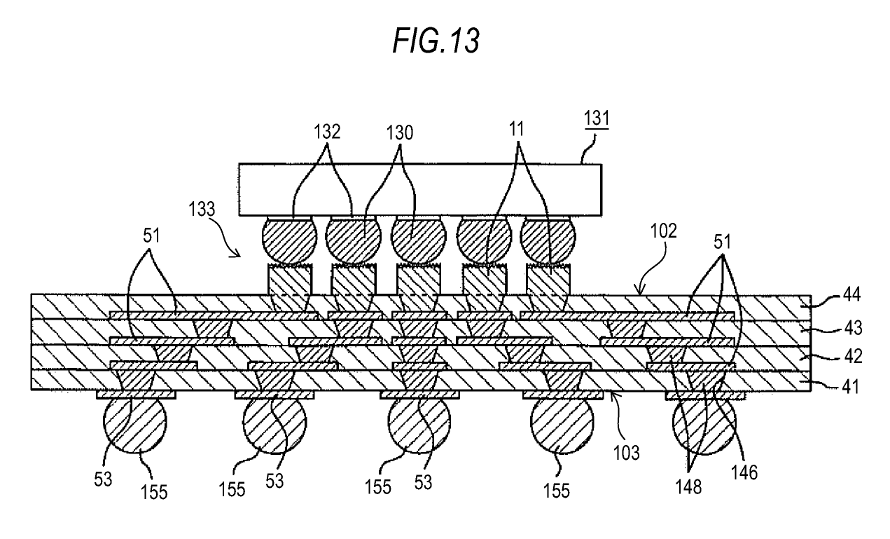

Thereafter, a process of mounting the IC chip is performed. More specifically, first, the IC chip 131 is placed in the electrode formation region 133 of the coreless wiring substrate 101 (refer to FIG. 13). At this time, the solder bumps 130 arranged at the bottom surface side of the IC chip 131 are placed on the upper surface 12 of the variant projection electrode 11 arranged at the coreless wiring substrate 101 side. Then, the respective solder bumps 130 are heated approximately at 230° C. to 260° C. and subjected to reflow soldering. Thereby, the variant projection electrode 11 is in the flip chip interconnection with respect to the connecting terminal 132 and the IC chip 131 is mounted on the coreless wiring substrate 101. In addition, the under filling 134 is filled in the clearance between the substrate main surface 102 of the coreless wiring substrate 101 and the IC chip 131 and subjected to hardening treatment. Then, the clearance is sealed using resin.

Therefore, according to the present embodiment, the following advantages can be obtained.

(1) In the coreless wiring substrate 101 of the present embodiment, all the projection electrodes which are present in the electrode formation region 133 become the variant projection electrodes 11 whose upper surfaces 12 are roughened. Consequently, if the solder bump 130 arranged at the bottom surface side of the IC chip 131 is placed on the upper surface 12 of the variant projection electrode 11, the upper surface 12 prevents the solder bump 130 from slipping and thereby the adhesive strength becomes high between the solder bump 130 and the variant projection electrode 11. As a result, since the solder bump 130 comes in contact with the upper surface 12 of the variant projection electrode 11, misalignment of the solder bump 130 is prevented. Accordingly, the IC chip 131 can be prevented in advance from falling out of a plurality of the variant projection electrodes 11 and consequently connection failure of the individual variant projection electrode 11 and the IC chip 131 can be prevented. That is, since the variant projection electrode 11 suitable for being connected to the IC chip 131 is provided, it is possible to improve the reliability of the coreless wiring substrate 101.

(2) In the present embodiment, all the projection electrodes which are present within the electrode formation region 133 become the variant projection electrodes 11. In this case, since the misalignment of a plurality of the solder bumps 130 is prevented by the multiple variant projection electrodes 11, it is possible to reliably prevent the IC chip 131 from falling out of a plurality of the variant projection electrodes 11.

(3) In the process of forming the variant projection electrode of the present embodiment, the upper surface 12 is roughened by pressing the upper surface 12 of the variant projection electrode 11 using the upper jig 162 which has the rough pressing surface 166. In this case, since the upper surfaces 12 of a plurality of the variant projection electrodes 11 is flattened, it is possible to reliably and easily obtain the coreless wiring substrate 101 which includes a group of the variant projection electrodes 11 which are excellent in coplanarity and suitable for being connected to the IC chip 131.

(4) In the process of forming the variant projection electrode of the present embodiment, pressing power is easy to be concentrated on the electrode formation region 133 during pressing the projection electrode 10. However, the multilayer portion 80 is entirely supported by the lower jig 163. As a result, the multilayer portion 80 is prevented from being bent. Therefore, it is possible to reliably and easily obtain the coreless wiring substrate 101 which includes a group of the variant projection electrodes 11 which are excellent in coplanarity.

In addition, the above-described embodiment may be modified as follows.

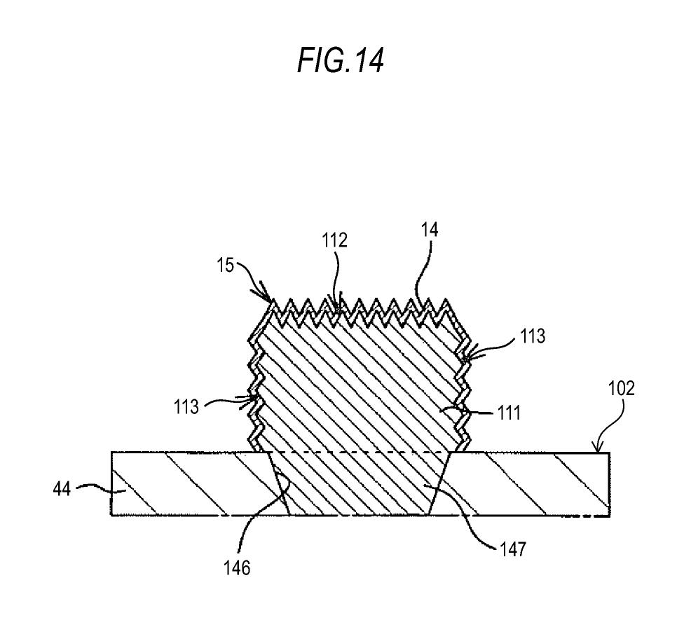

In the above-described embodiment, the variant projection electrode 11 where only the upper surface 12 is roughened is used. However, as illustrated in FIG. 14, the variant projection electrode 111 whose lateral surface 113 is roughened in addition to the upper surface 112 may be used. In this case, when heating and melting the solder bump placed on the upper surface 112 of the variant projection electrode 111 during connecting the IC chip to the variant projection electrode 111, the adhesive strength becomes high between the lateral surface 113 of the variant projection electrode 111 and the solder in addition to the adhesive strength between the upper surface 112 of the variant projection electrode 111 and the IC chip. Therefore, the IC chip can be more stably supported by the coreless wiring substrate. Furthermore, the lateral surface 113 is roughened by etching, for example.

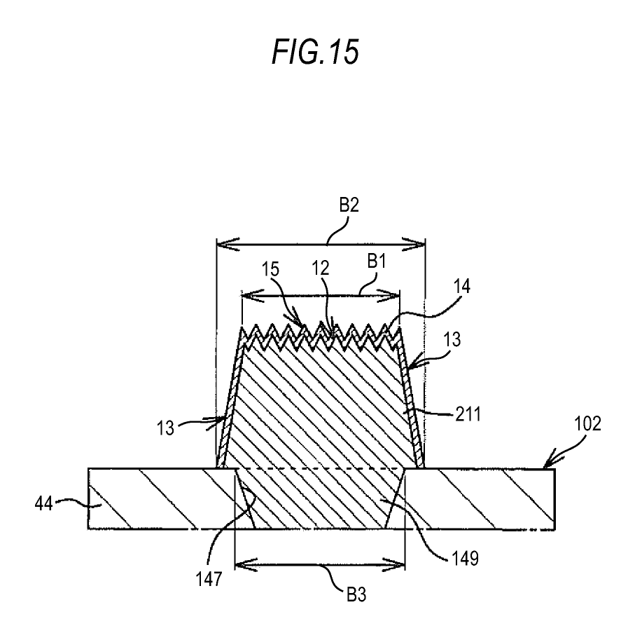

The variant projection electrode 11 of the above-described embodiment is set to have an equal outer diameter from the upper end to the lower end and is formed in the shape of a column as a whole. However, the shape of the variant projection electrode 11 is not limited thereto. For example, as illustrated in FIG. 15, an outer diameter B1 at the upper end may be set to be smaller than an outer diameter B2 at the lower end, and the outer diameter B2 at the lower end may be set to be larger than an outer diameter B3 at the upper end of a via conductor 149. A variant projection electrode 211 may have a trapezoidal shape in cross-section as a whole.

The variant projection electrode 11 of the above-described embodiment is integrally formed with the via conductor 149 provided at the top layer, the resin insulation layer 44, but may be formed separately from the via conductor 149.

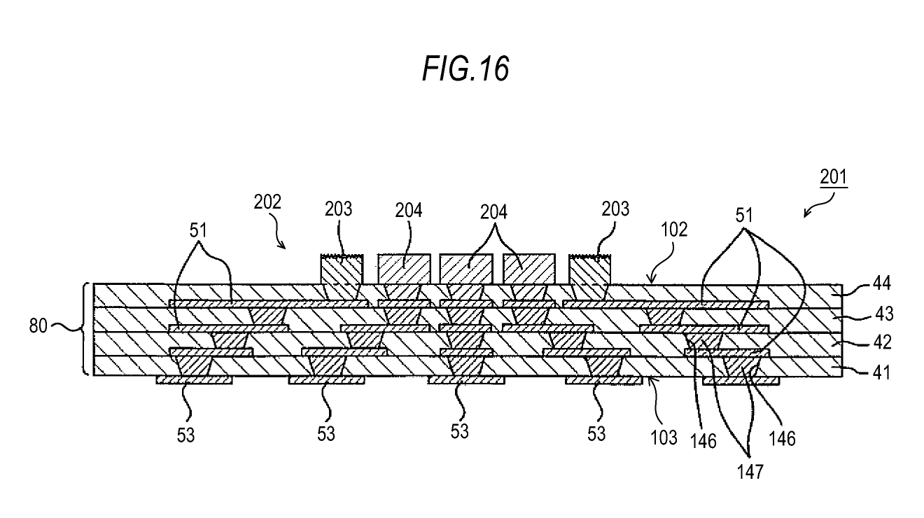

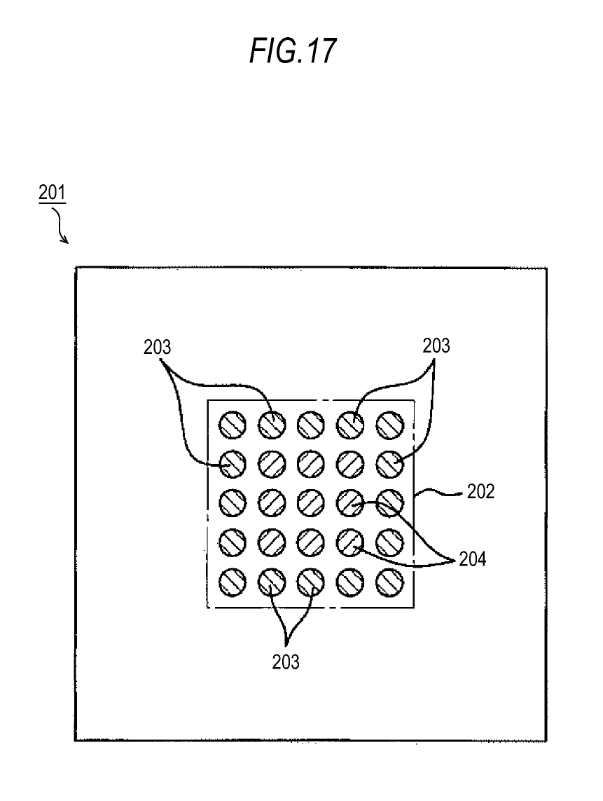

In the above-described embodiment, all the projection electrodes which are present within the electrode formation region 133 become the variant projection electrodes 11. However, as a coreless wiring substrate 201 illustrated in FIGS. 16 and 17, only the projection electrodes positioned at the outer periphery of an electrode formation region 202 among a plurality of the projection electrodes may become variant projection electrodes 203. Furthermore, projection electrodes 204 positioned at the region other than the outer periphery of the electrode formation region 202 are the cylindrical electrodes where the outer diameter at the upper end is set to be equal to the outer diameter at the lower end. In addition, the method of roughening only the projection electrodes positioned at the outer periphery of the electrode formation region 202 is not specifically limited. However, for example, only the projection electrodes at the outer periphery of the electrode formation region 202 can be selectively roughened using the electrode roughening device 161 (refer to FIG. 12) described in the above embodiment.

In the coreless wiring substrate 101 of the above-described embodiment, the variant projection electrodes 11 are formed only on the substrate main surface 102, but are not limited thereto. For example, the variant projection electrodes 11 may be formed on both the substrate main surface 102 and the substrate reverse surface 103.

In the above-described embodiment, the package form of the coreless wiring substrate 101 is a BGA (ball grid array), but is not limited only to the BGA. For example, a PGA (pin grid array), an LGA (land grid array) or the like may be used.

In the process of forming the variant projection electrode of the above-described embodiment, the upper surface 12 is roughened (and flattened) by pressing the upper surface 12 of plural projection electrodes 10 using the upper jig 162. That is, in the process of forming the variant projection electrode of the above-described embodiment, the upper surface 12 of the projection electrode 10 is mechanically roughened.

However, in the process of forming the variant projection electrode, the upper surface 12 of the projection electrode 10 may be chemically roughened. For example, the upper surface 12 of the projection electrode 10 may be roughened by etching with respect to the projection electrodes 10. In addition, after the lower portion of the projection electrode 10 is formed under the common plating condition, the upper portion of the projection electrode 10 may be formed under the different plating condition from the common plating condition. In this manner, the variant projection electrode 11 where the upper surface 12 is roughened may be formed. Here, as the method of changing the plating condition, for example, decreasing the mixing amount for the plating in a plating bath, increasing or decreasing the amount of brightener which is to be contained in the plating, adding a weak acid (for example, sodium hypochlorite or the like) to the plating, or the like may be exemplified. That is, it may be considered that the plating condition may be changed on purpose to the condition which causes soldering defects, such as pits or irregularities.

In addition, in the process of forming the variant projection electrode, the upper surface 12 of the projection electrode 10 may be mechanically roughened, of course. For example, the upper surface 12 of the projection electrode 10 may be roughened by sand blasting. In addition, the upper surface 12 of the projection electrode 10 may be roughened by surface grinding. The roughening by the surface grinding will be described in detail as follows. That is, the multilayer portion 80 which has a plurality of the projection electrodes 10 is placed on a vacuum holding plate which has multiple through holes, air pressure of the lower surface side of the vacuum holding plate is decreased and the multilayer portion 80 is fixed by the vacuum holding. Next, the upper surfaces 12 of the plural projection electrodes 10 are ground in a lump using a grinding machine which has a rotary grinding plate such as a grinder. Furthermore, as the grinding method, both a dry process and a wet process can be used.

In the above-described embodiment, during the process of forming the projection electrode, the projection electrode 10 formed from the copper layer and the nickel layer is formed, and the gold layer 14 (surface plated layer) is formed with respect to the surface of the variant projection electrode 11 (nickel layer) by performing the electroless displacement gold plating, after the process of forming the variant projection electrode. However, the method of forming the projection electrode or the surface plated layer is not specifically limited to the forming method of the above-described embodiment. For example, in the process of forming the projection electrode, the projection electrode formed only from the copper layer may be formed, and a tin layer (surface plated layer) or the nickel layer may be formed by performing the electroless displacement tin plating or displacement nickel plating with respect to the surface of the variant projection electrode (copper layer), after the process of forming the variant projection electrode. In addition, the surface plated layer may not specifically be formed.

Thus, the above-described embodiment can provide at least the following.

First, the embodiment can provide a wiring substrate where a via conductor provided at the interlayer insulation layers has a diameter which expands toward the substrate main surface side, and an outer diameter of the variant projection electrode is set to be larger than an outer diameter at the substrate main surface side of the via conductor.

The embodiment can also provide a method of manufacturing a wiring substrate where the process of forming the variant projection electrode includes a process of roughening the upper surface by pressing the upper surface of the projection electrode using a pressing jig which has a rough pressing surface, and a surface roughness Ra of the rough pressing surface is from 0.1 μm to 0.6 μm.

What is claimed is:

1. A wiring substrate comprising:
a multilayer portion which has a substrate main surface and a substrate reverse surface, the multilayer portion including interlayer insulation layers and a conductor layer that are layered;
a plurality of projection electrodes arranged within an electrode formation region on the substrate main surface; and
via conductors, which electrically connect the plurality of projection electrodes and the conductor layer to each other, provided at a top layer, which is the interlayer insulation layer which forms the substrate main surface;
wherein at least one among the plurality of projection electrodes has a larger outer diameter than an outer diameter of the respective via conductor and is a variant projection electrode which has a roughened upper surface.

2. The wiring substrate according to claim 1,
wherein the variant projection electrode has a roughened lateral surface in addition to the roughened upper surface.

3. The wiring substrate according to claim 1,
wherein a surface roughness Ra of the variant projection electrode is from 0.1 μm to 0.6 μm.

4. The wiring substrate according to claim 1,
wherein the variant projection electrode has an equal outer diameter from an upper end to a lower end and is formed in a shape of a column as a whole.

5. The wiring substrate according to claim 1,
wherein all of the plurality of projection electrodes which are present within the electrode formation region comprise variant projection electrodes.

6. The wiring substrate according to claim 1,
wherein the plurality of projection electrodes are arrayed in vertical and horizontal rows along a surface direction of the substrate main surface within the electrode formation region, and
wherein, among the plurality of projection electrodes, projection electrodes positioned at an outer periphery of the electrode formation region comprise variant projection electrodes.

7. The wiring substrate according to claim 1,
wherein the variant projection electrode is in a flip chip interconnection with a connecting terminal arranged at a bottom surface side of a component via a solder bump placed on the upper surface of the variant projection electrode.

8. A method of manufacturing a wiring substrate, comprising:
preparing a multilayer portion which has a substrate main surface and a substrate reverse surface, the multilayer portion including interlayer insulation layers and a conductor layer that are layered;
forming a via hole which penetrates a top layer, which is the interlayer insulation layer which forms the substrate main surface;
forming a resist on the top layer;
forming an opening on the resist which has a larger inner diameter than that of the via hole;
forming a via conductor at the via hole and a projection electrode at the opening by plating the inner side of the via hole and the opening; and
forming a variant projection electrode by roughening an upper surface of the projection electrode.

9. The method of manufacturing a wiring substrate according to claim 8,
wherein, in forming the variant projection electrode, the upper surface of the projection electrode is roughened by etching the projection electrode.

10. The method of manufacturing a wiring substrate according to claim 8,
wherein, informing the variant projection electrode, the upper surface of the projection electrode is roughened by pressing the upper surface of the projection electrode using a pressing jig which has a rough pressing surface.

11. The method of manufacturing a wiring substrate according to claim 9,
wherein, after forming the variant projection electrode, a surface plated layer which has a roughened surface corresponding to a shape of the upper surface of the variant projection electrode is formed on a surface of the variant projection electrode by displacement plating.

12. The method of manufacturing a wiring substrate according to claim 10,
wherein, after forming the variant projection electrode, a surface plated layer which has a roughened surface corresponding to a shape of the upper surface of the variant projection electrode is formed on a surface of the variant projection electrode by displacement plating.
